(19) United States
(12) Patent Application Publication
(10) Pub. No.: US 2020/0142237 A1
(43) Pub. Date: May 7, 2020

(54) DISPLAY MODULE AND MANUFACTURING METHOD THEREOF

(71) Applicant: WUHAN CHINA STAR OPTOELECTRONICS TECHNOLOGY CO., LTD., Wuhan, Hubei (CN)

(72) Inventor: Yingbo ZHENG, Wuhan, Hubei (CN)

(73) Assignee: WUHAN CHINA STAR OPTOELECTRONICS TECHNOLOGY CO., LTD., Wuhan, Hubei (CN)

(21) Appl. No.: 16/342,978

(22) PCT Filed: Sep. 11, 2018
(86) PCT No.: PCT/CN2018/105048

§ 371 Date: Apr. 18, 2019

(30) Foreign Application Priority Data
Sep. 6, 2018 (CN) 201810832323.5

(51) Int. Cl. G02F 1/1345; H05K 3/32; H05K 1/18

(52) U.S. Cl. CPC G02F 1/13452; G02F 1/13458; H05K 2201/10136; H05K 1/189; H05K 3/323

(57) ABSTRACT

A display module and a manufacturing method of a display module are disclosed. The manufacturing method includes: forming a metal layer in the vias and on the array substrate thereby to cause the metal layer in the vias to form connecting terminals; providing a pattern treatment for the metal layer on the array substrate to form a plurality of metal wires and the metal wires disposed correspondingly to the vias; and cutting off a part of the array substrate disposed at an outer side of the vias to expose the connecting terminals at a sidewall of a remaining part of the array substrate.

### FIELD OF INVENTION

The present invention relates to a display module, and more specifically, to a manufacturing method of a display module.

### BACKGROUND

In current mobile terminal market, the demand for mobile terminals with a high-screen ratio keeps growing. Therefore, narrowing edge frames of a liquid crystal display (LCD) has become a recent hot research topic.

Referring to FIG. 1, a conventional electronic device includes a narrow edge frame LCD display panel. The narrow edge frame LCD display panel 10 includes a display region 101 and a non-display region. The non-display region includes a binding area 102. Referring to FIG. 2, a cross-sectional structure of the LCD display panel 10 includes an array substrate 11 and a color film substrate 12. Connecting terminals 13 are disposed on a surface of the array substrate 11 to bind a flexible circuit board 20 on the array substrate 11 using an anisotropic conductive film (ACF). The flexible circuit board 20 is a chip on film (COF) or a flexible printed circuit (FPC). The connecting terminals 13 are electrically connected to a panel control chip 21 and a signal line of LCD display panel.

A solder point is disposed between the connecting terminal 13 and the flexible printed circuit 20. Furthermore, the solder point is disposed on a lower edge of the LCD display panel or an electronic device and results in a larger size of the binding area (2.0 mm) and a smaller display area.

Thus, a display module and a manufacturing method thereof for solving the aforementioned issues shall be provided.

### SUMMARY OF THE INVENTION

The present invention provides a display module and a manufacturing method thereof to decrease the size of the frame and to increase the display area. In order to solve those technical issues, the present invention provides a manufacturing method of a display module, comprising: providing a display panel, comprising:

1. providing an array substrate provided with a display region and a solder region;

2. forming a plurality of vias on the array substrate and in the solder region;

3. forming a metal layer in the vias and on the array substrate thereby to cause the metal layer in the vias to form connecting terminals;

4. providing a pattern treatment for the metal layer on the array substrate to form a plurality of metal wires and the metal wires disposed correspondingly to the vias;

5. cutting off a part of the array substrate disposed at an outer side of the vias to expose the connecting terminals at a sidewall of a remaining part of the array substrate, wherein the outer side of the vias is a side away from the metal wires; and

6. connecting electrically the connecting terminals to a flexible printed circuit to form a binding area at the sidewall of the array substrate.

In a preferred embodiment of the present disclosure, the step of cutting off a part of the array substrate disposed at an outer side of the vias to expose the connecting terminals at a sidewall of a remaining part of the array substrate comprises: cutting off the array substrate along a line interconnecting geometric centers of the plurality of vias.

In a preferred embodiment of the present disclosure, a width of the binding area is equal to or less than 1 millimeter (mm).

In a preferred embodiment of the present disclosure, the width of the binding area ranges from 0.4 mm-0.6 mm.

In a preferred embodiment of the present disclosure, a step of connecting electrically the connecting terminals to a flexible printed circuit comprises: connecting electrically a sidewall of each of the connecting terminals to the flexible printed circuit.

In a preferred embodiment of the present disclosure, a step of connecting electrically the sidewall of each of the connecting terminals to the flexible printed circuit comprises: connecting electrically the sidewall of each of the connecting terminals to the flexible printed circuit using an anisotropic conductive film.

The present invention provides a display module, comprising:

a display panel comprising an array substrate comprising a plurality of metal wires and a plurality of connecting terminals disposed correspondingly to the metal wires; the metal wires disposed on the array substrate and the connecting terminals disposed on a sidewall of the array substrate.

In a preferred embodiment of the present disclosure, the array substrate comprises a binding area on the sidewall.

In a preferred embodiment of the present disclosure, the binding area is formed by connecting electrically a sidewall of each of the connecting terminals to a flexible printed circuit.

In a preferred embodiment of the present disclosure, the sidewall of each of the connecting terminals electrically connects the flexible printed circuit using an anisotropic conductive film.

In a preferred embodiment of the present disclosure, a width of the binding area is equal to or less than 1 millimeter (mm).

In a preferred embodiment of the present disclosure, the width of the binding area ranges from 0.4 mm-0.6 mm.

The present invention provides an electronic device, comprising:

a display module comprising:

a display panel comprising an array substrate comprising a plurality of metal wires and a plurality of connecting terminals disposed correspondingly to the metal wires; the metal wires disposed on the array substrate and the connecting terminals disposed at a sidewall of the array substrate.

In a preferred embodiment of the present disclosure, the array substrate comprises a binding area at a sidewall.

In a preferred embodiment of the present disclosure, the binding area is formed by connecting electrically the sidewall of each of the connecting terminals to a flexible printed circuit.

In a preferred embodiment of the present disclosure, the sidewall of each of the connecting terminals electrically connects the flexible printed circuit using an anisotropic conductive film.

In a preferred embodiment of the present disclosure, a width of the binding area is equal to or less than 1 millimeter (mm).

In a preferred embodiment of the present disclosure, the width of the binding area ranges from 0.4 mm-0.6 mm.

The display module and a manufacturing method thereof disclosed in the present invention utilize the connecting terminals of the metal wire in the display panel to mount on a sidewall to connect the flexible printed circuit and results in a smaller binding area, a smaller edge frame size and a larger display area.

### BRIEF DESCRIPTION OF THE DRAWINGS

FIG. 1 is a schematic top view diagram of a conventional electronic device.

FIG. 2 is a schematic diagram of a conventional display module.

FIG. 3 is a schematic diagram of a display module according to the present invention.

FIG. 4 is a schematic top view diagram during a display module manufacturing method according to the present invention.

FIG. 5 is a schematic diagram during a display module manufacturing method according to the present invention.

FIG. 6 is a schematic top view diagram of an electronic device according to the present invention.

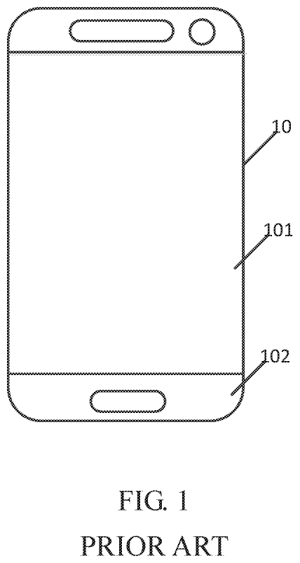

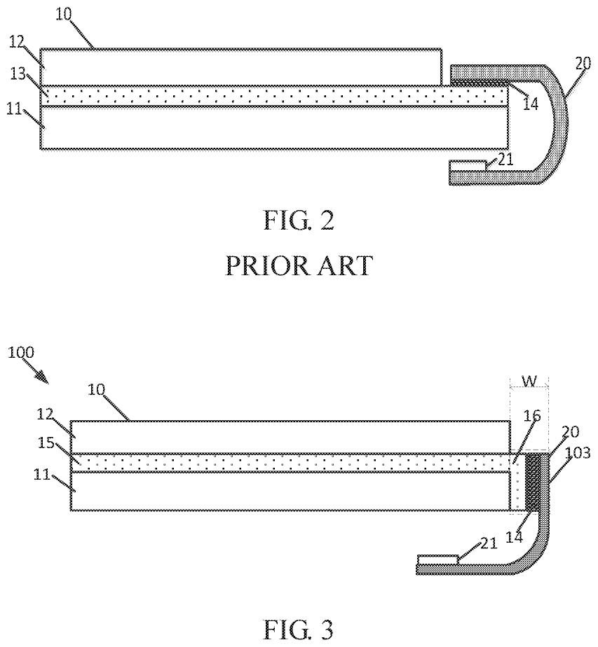

### DETAILED DESCRIPTION OF PREFERRED EMBODIMENTS

The embodiments of the present disclosure are described in detail hereinafter. Examples of the described embodiments are given in the accompanying drawings, wherein the identical or similar reference numerals constantly denote the identical or similar elements or elements having the identical or similar functions. In the description of the present disclosure, it should be understood that terms such as “upper,” “lower,” “front,” “rear,” “left,” “right,” “inside,” “outside,” “lateral,” as well as derivative thereof should be construed to refer to the orientation as then described or as shown in the drawings under discussion. These relative terms are for convenience of description, do not require that the present disclosure be constructed or operated in a particular orientation, and shall not be construed as causing limitations to the present disclosure.

Referring to FIGS. 3-6, FIG. 3 is a schematic diagram of a display module according to the present invention.

The present invention provides a display module 100. The display module 100 includes a display panel 10 which is a liquid crystal display (LCD) panel. The display panel 10 includes an array substrate 11 and a color film substrate 12. The array substrate 11 has a plurality of metal wires 15 and a plurality of connecting terminals 16 disposed correspondingly to the metal wires 15. The metal wires are disposed on the array substrate 11 and the connecting terminals 16 are disposed on a sidewall of the array substrate 11.

In a preferred embodiment of the present disclosure, the array substrate 11 includes a binding area 103 on the sidewall.

In a preferred embodiment of the present disclosure, the binding area 103 is formed by connecting electrically a sidewall of each of the connecting terminals 16 to a flexible printed circuit 20. The sidewall of each of the connecting terminals 16 electrically connects the flexible printed circuit 20 using an anisotropic conductive film (ACF). The anisotropic conductive film (ACF) contains metal particles. The present invention utilizes the binding area 103 disposed on the sidewall of the display panel 10 to decrease lower edge size of the display panel 10 and to increase the display area.

In a preferred embodiment of the present disclosure, in order to decrease lower edge size of the display panel 10, a width of the binding area is equal to or less than 1 millimeter (mm). For example, the width of the binding area ranges from 0.4 mm-0.6 mm. The color film substrate 12 includes a first substrate, a color resistance layer on the first substrate and a black matrix.

The present invention provides a manufacturing method of a display module, comprising:

S10: Providing a display panel, comprising:

S101: Providing an array substrate 11. For example, forming sequentially a switch array layer and the switch array layer includes a plurality of switch components. A cross-sectional structure includes a gate, a channel, a source electrode and a drain electrode.

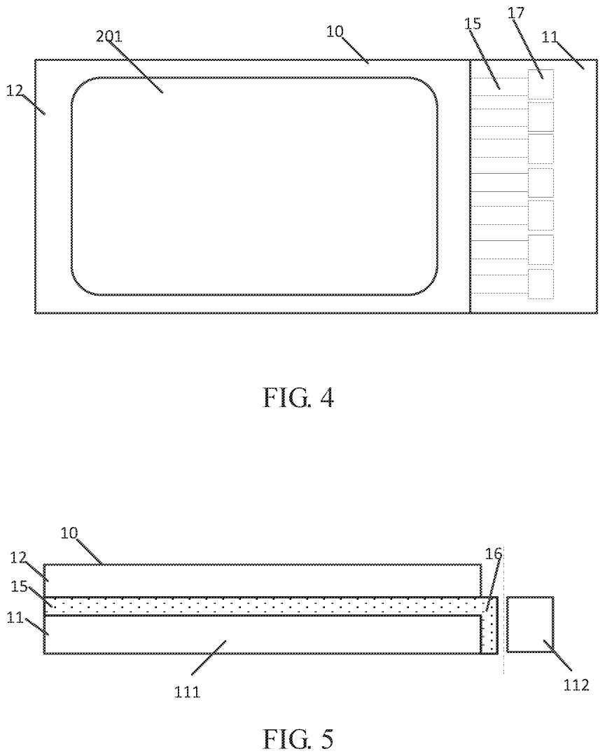

S102: Forming a plurality of vias 17 on the array substrate 11. For example, referring to FIG. 4, the array substrate 11 provided with a display region 201 and a solder region. The solder region is outside the display region 201. Forming a plurality of vias 17 on the array substrate 11 and in the solder region. The vias 17 extending from an upper surface of the array substrate 11 to a lower surface of the array substrate 11. The shapes of the vias 17 can be a circle or a rectangle.

S103: Forming a metal layer in the vias 17 and on the array substrate 11 thereby to cause the metal layer in the vias 17 to form connecting terminals 16. For example, forming a metal layer on the array substrate 11 and in the vias 17 thereby to cause the metal layer in the vias 17 to form connecting terminals 16.

S104: Providing a pattern treatment for the metal layer on the array substrate to form a plurality of metal wires. For example, coating glues on the vias 17 to prevent the metal layer from etching. Then, the metal layer on the array substrate 11 is exposed, developed and etched to form a plurality of metal wires 15. The metal wires are the metal layer along a horizontal direction and the connecting terminals 16 are the metal layer along a vertical direction. The metal wires 15 are disposed correspondingly to the vias 17.

S105: Cutting off a part of the array substrate 11 disposed at an outer side of the vias 17 to expose the connecting terminals 16 at a sidewall of a remaining part of the array substrate 11, wherein the outer side of the vias 17 is a side away from the metal wires 15. Then, edging the remaining part of the array substrate 11 to level the sidewalls of the array substrate 11.

In order to reduce the later manufacturing process and to improve the production efficiency, the step S105 includes cutting off a part of the array substrate 11 disposed at an outer side of the vias 17 to expose the connecting terminals 16 at a sidewall of a remaining part of the array substrate 11 and further includes a step S1051.

S1051: cutting off the array substrate 11 along a line interconnecting geometric centers of the plurality of vias 17. For example, cutting the array substrate 11 along a line interconnecting geometric centers of the plurality of vias 17. If the vias are circular, circular centers of vias 17 are connected with one another to form cutting lines.

S11: Connecting electrically the connecting terminals 16 to a flexible printed circuit 20 to form a binding area 103 on the sidewall of the array substrate 11. For example, referring to FIG. 3, the present invention utilizes connecting electrically the connecting terminals 16 to a flexible printed circuit 20 to form a binding area 103 on the sidewall of the array substrate 11. In one embodiment, the sidewall of each of the connecting terminals 16 electrically connects the flexible printed circuit 20 using an anisotropic conductive film (ACF) 14. The anisotropic conductive film (ACF) 14 contains metal particles. The flexible printed circuit 20 includes a drive chip 21 for inputting the drive signals to the display panel 10. Aforementioned method further includes providing a color film substrate and later process to finish the manufacturing of the display panel 10. The present invention utilizes the binding area 103 disposed on the sidewall of the display panel 10 to decrease lower edge size of the display panel 10 and to increase the display area.

In order to decrease lower edge size of the display panel 10, a width of the binding area is equal to or less than 1 millimeter (mm). For example, the width of the binding area ranges from 0.4 mm-0.6 mm.

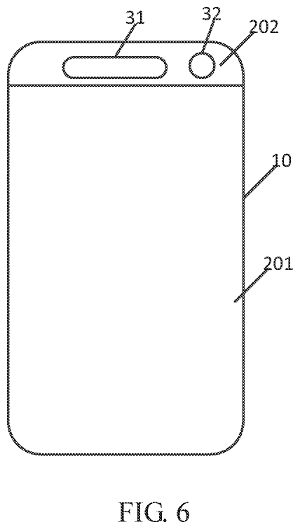

Referring to FIG. 6, the present invention provides an electronic device having a display panel 10. The display panel 10 includes a display region 201 and a non-display region 202. The non-display region 202 is located on the electronic device. The non-display region 202 includes a sensing component 31 and a camera 32.

The present invention utilizes the binding area 103 disposed on the sidewall of the display panel 10 to decrease lower edge size of the display panel 10 and to increase the display area.

The display module and a manufacturing method thereof disclosed in the present invention utilize the connecting terminals 16 of the metal wire 15 in the display panel 10 to mount on a sidewall to connect the flexible printed circuit 20 and results in a smaller binding area, a smaller edge frame size and a larger display area.

The present disclosure has been described with a preferred embodiment thereof. The preferred embodiment is not intended to limit the present disclosure, and it is understood that many changes and modifications to the described embodiment can be carried out without departing from the scope and the spirit of the disclosure that is intended to be limited only by the appended claims.

What is claimed is:

1. A manufacturing method of a display module, comprising:
providing a display panel, comprising:
providing an array substrate provided with a display region and a solder region;
forming a plurality of vias on the array substrate and in the solder region;
forming a metal layer in the vias and on the array substrate thereby causing the metal layer in the vias to form connecting terminals;
providing a pattern treatment for the metal layer on the array substrate to form a plurality of metal wires, wherein the metal wires are correspondingly disposed to the vias;
cutting off a part of the array substrate disposed at an outer side of the vias to expose the connecting terminals at a sidewall of a remaining part of the array substrate, wherein the outer side of the vias is a side away from the metal wires; and
connecting electrically the connecting terminals to a flexible printed circuit to form a binding area at the sidewall of the array substrate.

2. The manufacturing method of a display module according to claim 1, wherein the step of cutting off a part of the array substrate disposed at an outer side of the vias to expose the connecting terminals at a sidewall of a remaining part of the array substrate comprises:
cutting off the array substrate along a line interconnecting geometric centers of the plurality of vias.

3. The manufacturing method of a display module according to claim 1, wherein a width of the binding area is equal to or less than 1 millimeter (mm).

4. The manufacturing method of a display module according to claim 3, wherein the width of the binding area ranges from 0.4 mm-0.6 mm.

5. The manufacturing method of a display module according to claim 1, wherein a step of connecting electrically the connecting terminals to a flexible printed circuit comprises: connecting electrically a sidewall of each of the connecting terminals to the flexible printed circuit.

6. The manufacturing method of a display module according to claim 5, wherein a step of connecting electrically the sidewall of each of the connecting terminals to the flexible printed circuit comprises: connecting electrically the sidewall of each of the connecting terminals to the flexible printed circuit using an anisotropic conductive film.

7. A display module, comprising:
a display panel comprising an array substrate comprising a plurality of metal wires and a plurality of connecting terminals disposed correspondingly to the metal wires; the metal wires disposed on the array substrate and the connecting terminals are disposed on a sidewall of the array substrate.

8. The display module according to claim 7, wherein the array substrate comprises a binding area on the sidewall.

9. The display module according to claim 8, wherein the binding area is formed by connecting electrically a sidewall of each of the connecting terminals to a flexible printed circuit.

10. The display module according to claim 9, wherein the sidewall of each of the connecting terminals electrically connects the flexible printed circuit using an anisotropic conductive film.

11. The display module according to claim 8, wherein a width of the binding area is equal to or less than 1 millimeter (mm).

12. The display module according to claim 11, wherein the width of the binding area ranges from 0.4 mm-0.6 mm.

13. An electronic device, comprising:
a display module comprising:
a display panel comprising an array substrate comprising a plurality of metal wires and a plurality of connecting terminals disposed correspondingly to the metal wires; the metal wires disposed on the array substrate and the connecting terminals disposed at a sidewall of the array substrate.

14. The electronic device according to claim 13, wherein the array substrate comprises a binding area at a sidewall.

15. The electronic device according to claim 14, wherein the binding area is formed by connecting electrically the sidewall of each of the connecting terminals to a flexible printed circuit.

16. The electronic device according to claim 15, wherein the sidewall of each of the connecting terminals electrically connects the flexible printed circuit using an anisotropic conductive film.

17. The electronic device according to claim 14, wherein a width of the binding area is equal to or less than 1 millimeter (mm).

18. The electronic device according to claim 17, wherein the width of the binding area ranges from 0.4 mm-0.6 mm.
